(19) United States
(12) Patent Application Publication
(10) Pub. No.: US 2026/0371818 A1
(43) Pub. Date: Nov. 19, 2026

(54) MULTI-FUNCTIONAL LAYER

(71) Applicant: VueReal Inc., Waterloo (CA)

(72) Inventors: Chang-Ho Park, Burlington (CA); Kai-Wen Cheng, Waterloo (CA)

(73) Assignee: VueReal Inc., Waterloo, OT (CA)

(21) Appl. No.: 19/583,337

(22) PCT Filed: Nov. 3, 2024
(86) PCT No.: PCT/IB2024/060846

§ 371 Date: Apr. 29, 2026

Related U.S. Application Data
(60) Provisional application No. 63/596,113, filed on Nov. 3, 2023.

(51) Int. Cl. H10H 29/851; H10H 29/01; H10H 29/14; H10H 29/856

(52) U.S. Cl. CPC H10H 29/851; H10H 29/034; H10H 29/14; H10H 29/856

(57) ABSTRACT

The present disclosure relates to methods to add one or more multi-functional layers on a backplane of a microLED array to deal with specific functions of the microLED. In particular, adding a color conversion layer, a high contrast ratio layer or a mirror functional layer to the backplane.

### CROSS-REFERENCE TO RELATED APPLICATIONS

This application claims priority to, and benefit of, U.S. Provisional Patent Application No. 63/596,113 filed Nov. 3, 2023, which is hereby incorporated by reference herein in its entirety.

### FIELD OF THE INVENTION

The present disclosure relates to various improvements in MicroLED display technology, in particular to deal with specific functions to a microLED array on a backplane.

### SUMMARY

The present invention relates to a method to add one or more multi-functional layers on a backplane of a microLED array to deal with specific functions of the microLED array. The method includes having a color conversion layer added to the backplane. The color conversion layer includes a bank structure with diffuse reflective coating, a bounding at other side, a phosphor coating and an optical reflection coating.

The present invention relates to a method to add one or more multi-functional layers on a backplane of a microLED to deal with specific functions of the microLED array. The method includes having a high contrast ratio layer added to the backplane. The high contrast ratio layer includes an optical structure design with an optical absorption coating and an encapsulation layer for heat isolation and protection.

The present invention relates to a method to add one or more multi-functional layers on a backplane of a microLED array to deal with specific functions of the microLED array. The method includes having a mirror functional layer added to the backplane. The mirror functional layer includes an optical structure design with an optical reflection coating and an encapsulation layer for heat isolation and protection.

### BRIEF DESCRIPTION OF THE DRAWINGS

The foregoing and other advantages of the disclosure will become apparent upon reading the following detailed description and upon reference to the drawings.

FIG. 1 shows a multi-functional layer.

FIG. 2 shows a full color conversion layer.

FIG. 3A shows a full color conversion layer-bank design structure.

FIG. 3B shows a bank structure matrix array.

FIG. 4 shows a process flow concept for full conversion layer

FIG. 5 shows a high contrast ratio layer.

FIG. 6 shows a process flow concept for high contrast ratio layer.

FIG. 7 shows a mirror functional layer.

FIG. 8 shows a process flow concept for mirror functional layer.

While the present disclosure is susceptible to various modifications and alternative forms, specific embodiments or implementations have been shown by way of example in the drawings and will be described in detail herein. It should be understood, however, that the disclosure is not intended to be limited to the particular forms disclosed. Rather, the disclosure is to cover all modifications, equivalents, and alternatives falling within the spirit and scope of an invention as defined by the appended claims.

### DETAILED DESCRIPTION

In one related embodiment, a reflective surface is used to reflect the image of a display to the viewers. Here, at least one transparent display is used, and a second display is set behind the transparent display. As a result, the two images created for the two displays can be perceived at different distances from the reflective surface.

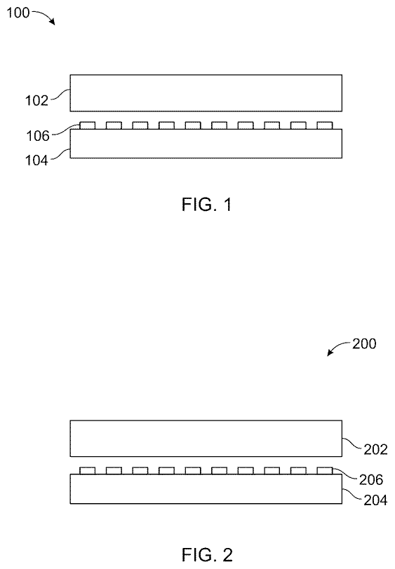

FIG. 1 shows a system 100 of a multi-functional layer 102. This multi-functional layer 102 comprises Full conversion layer, high contrast ratio layer and mirror functional layer. The full conversion layer is made from phosphor-based structure. The high contrast ratio layer has optical absorption coating. The Mirror functional layer works as optical reflection coating. The backplane 104 is covered with a multi-functional layer. The microLED 106 embedded on backplane 104. The conventional microLED display comprises of a microLED array on the backplane. The main function is only for display; however, one can add one or more multi-functional layers on it to deal with specific functions.

FIG. 2 shows a structure 200 for full color conversion layer 202. The full color conversion layer 202, wherein 206 is a MicroLED and 204 is the backplane, comprises of:
1. One or more different color phosphors. Ex: Yellow or Red/Green phosphor.
2. One or more different particle size phosphors. Ex: 1~10 um or 0.1~0.9 um.
3. Optical structure design based on requirements. Ex: bank, reflective coating, roughness.
4. Encapsulation layer for heat isolation and protection.

Full conversion layer 202 cover the microLED's 206. MicroLED 206 are mounted on backplane 204.

If it is possible to treat a specific color conversion part, it is then may be possible to make a monochrome display as a full color display by selecting suitable color phosphor and assembling it.

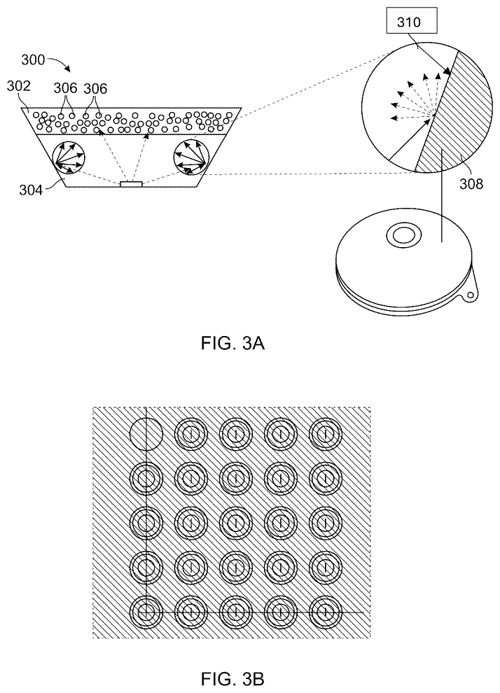

FIG. 3A shows a full color conversion layer adding process. FIG. 3A shows a Full color conversion layer with bank structure 300 with a diffusive reflective coating 304, remote phosphor 306, and an edge border angle which may be withing a range of less than 180 degrees. For example, it can be 30 degrees. The material 308 after the diffuse reflective coating provides a support. The material 308 may be polymer, photoresist, PC or PMMA etc. There is a roughness surface 310 at the angular edge. There can be a diffusive texture over the material 308. Diffusive texture means there could be any type of surface process, lit could be a roughness surface, reflective surface or a mirror surface.

FIG. 3B shows a bank structure matrix array.

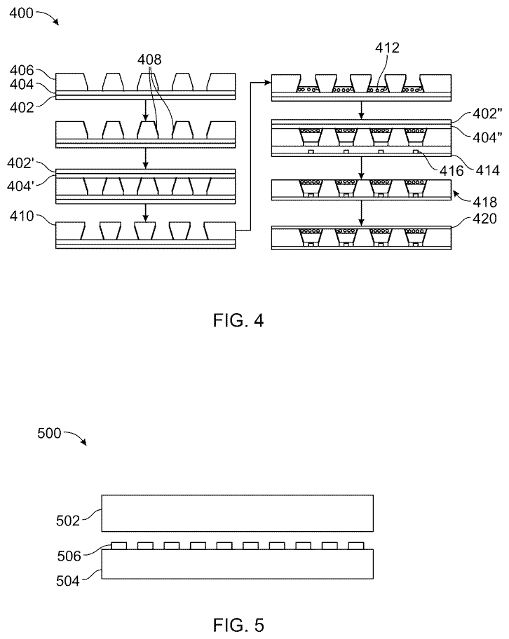

FIG. 4 shows a process flow concept 400 for addition of a full conversion layer. The addition of full color conversion process which provide a substrate 402 covering with release layer 404 and bank structure 406 with edge border angle 408 at less than 180 degrees over that release layer 404 to make a bank structure array. Diffuse or spread a reflective coating over the micro devices 406. Now bounding at the other side of bank structure 406 with release layer 404′ and then substrate 402′. After bounding the other side reverse the structure and release the top layer of release layer 404″ and substrate 402″. Apply the phosphor coating 412 above the release layer in between the bank structure. Now reverse the substrate and bound bank structure array with the back plane holding an array of microdevices 416. Now release the substrate 402 and release layer 404. And coat with an encapsulation layer to protect it from heat. The backplane 404 is covered with multi-functional layer. The microLED's 416 are embedded on backplane 404. The conventional microLED display comprises of a microLED array on the backplane.

FIG. 5 shows a high contrast ratio layer 502 along with a microLED's 506 on a backplane 504. The high contrast ratio layer may comprise of the following parts:
1. Optical structure design based on requirements.
2. Optical absorption coating.
3. Encapsulation layer for heat isolation and protection.

By adding this high contrast ratio layer, it may be possible to select specific wavelengths to absorb or control the transmittance in specific wavelengths. For a case to absorb a full visible wavelength, it will become a black matrix (BM) to eliminate the optical crosstalk from each pixel and become the high contrast ratio display.

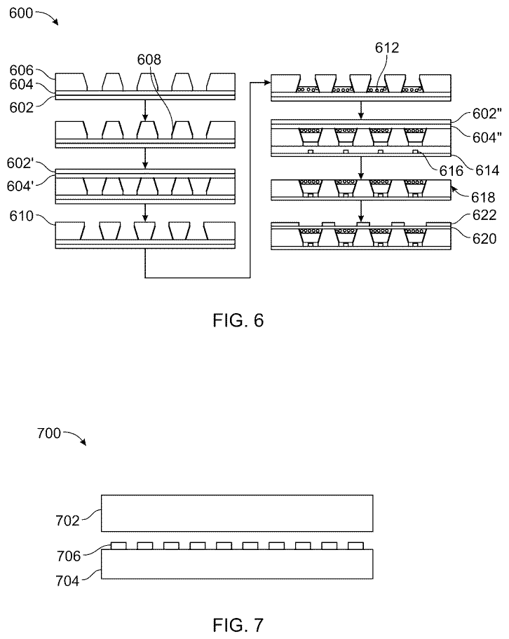

FIG. 6 shows a process flow concept for a high contrast ratio layer 600. The addition of full color conversion process which provide a substrate 602 covering with release layer 604 and bank structure 606 with edge border angle 608 at less than 180 degrees over that release layer 604 to make a bank structure array. Diffuse or spread a reflective coating over the bank structure array. Now bounding at the other side of bank structure 606 with release layer 604′ and then substrate 602′. After bounding the other side reverse the structure and release the top layer of release layer 604″ and substrate 602″. Apply the phosphor coating 612 above the release layer in between the bank structure. Now reverse the substrate and bound bank structure array with the back plane holding an array of microdevices 616. Now release the substrate 602 and release layer 604. And coat with an encapsulation layer to protect it from heat. The backplane 604 is covered with a multi-functional layer. The microLED's 616 are embedded on backplane 604. The conventional microLED display comprises of a microLED array on the backplane.

FIG. 7 shows a mirror functional layer 702. The mirror functional layer 702 comprises:
1. Optical structure design based on requirements.
2. Optical reflection coating.
3. Encapsulation layer for heat isolation and protection.

By adding this mirror functional layer, it may be possible to select specific wavelengths to reflect or control the reflectance in specific wavelengths. To reflect the full visible wavelength, it will become a mirror display just like a normal mirror, but when the display is turned on, it will become a functional mirror display.

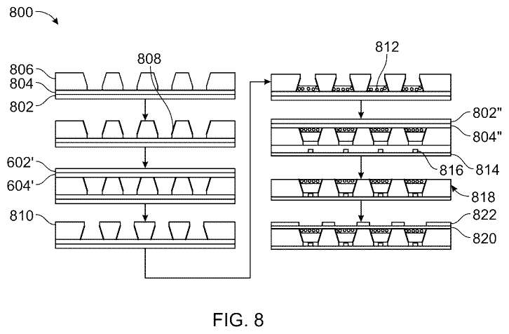

FIG. 8 shows a process flow concept for a mirror functional layer 800. The addition of full color conversion process which provide a substrate 802 covering with release layer 804 and bank structure 806 with edge border angle 808 at less than 180 degrees over that release layer 804 to make a bank structure array. Diffuse or spread a reflective coating over the bank structure array. Now bounding at the other side of bank structure 606 with release layer 604′ and then substrate 602′. After bounding the other side reverse the structure and release the top layer of release layer 804″ and substrate 802″. Apply the phosphor coating 812 above the release layer in between the bank structure. Now reverse the substrate and bound bank structure array with the back plane holding an array of microdevices 816. Now release the substrate 802 and release layer 804. And coat with an encapsulation layer to protect it from heat. The backplane 804 is covered with a multi-functional layer. The microLED's 816 are embedded on backplane 804. The conventional microLED display comprises of a microLED array on the backplane.

While the present disclosure is susceptible to various modifications and alternative forms, specific embodiments or implementations have been shown by way of example in the drawings and will be described in detail herein. It should be understood, however, that the disclosure is not intended to be limited to the forms disclosed. Rather, the disclosure is to cover all modifications, equivalents, and alternatives falling within the spirit and scope of an invention as defined by the appended claims.

1-3. (canceled)

4. A microLED array comprising:
a backplane;
a plurality of microLEDs at least partially embedded in the backplane; and
a multi-functional layer disposed over the backplane and the plurality of microLEDs, the multi-functional layer including one or more layers configured to modify light emitted by the plurality of microLEDs.

5. The microLED array of claim 4, wherein the multi-functional layer includes a plurality of bank structures each disposed over a respective one of the plurality of microLEDs, each bank structure having edges with a diffusive reflective coating configured to internally reflect light emitted by the respective one microLED within the bank structure.

6. The microLED array of claim 5, wherein the edges of each bank structure are angled away from the respective one microLED at an angle of 30 degrees.

7. The microLED array of claim 5, wherein the multi-functional layer includes a color conversion layer, a high contrast ratio layer, a mirror functional layer, or any combination thereof.

8. The microLED array of claim 7, wherein each bank structure of the color conversion layer includes a phosphor coating configured to convert a color of light emitted by the respective one microLED.

9. The microLED array of claim 8, wherein the phosphor coating includes phosphor particles having one or more different colors, one or more different sizes, or both.

10. The microLED array of claim 7, wherein each bank structure of the high contrast ratio layer includes an optical absorption coating configured to absorb light of a predetermined wavelength from the respective one microLED.

11. The microLED array of claim 7, wherein each bank structure of the mirror functional layer has an optical reflection coating configured to reflect light of a predetermined wavelength from the respective one microLED.

12. A method for adding one or more multi-functional layers to a microLED array, the method comprising:
forming a bank structure array on a temporary substrate, the bank structure array including a plurality of bank structures;
depositing a diffusive reflective coating on edges of each of the plurality of bank structures;
applying an optical coating to the plurality of bank structures;
attaching the bank structure array to a backplane holding a plurality of microLEDs so that the temporary substrate is opposite the plurality of microLEDs; and
removing the temporary substrate.

13. The method of claim 12, wherein the edges of each bank structure are angled at an angle of 30 degrees.

14. The method of claim 12, wherein applying the optical coating includes applying a phosphor coating configured to convert a color of light emitted by the plurality of microLEDs.

15. The method of claim 14, wherein the phosphor coating includes phosphor particles having one or more different colors, one or more different sizes, or both.

16. The method of claim 12, wherein applying the optical coating includes applying an optical absorption coating configured to absorb light of a predetermined wavelength from the plurality of microLEDs.

17. The method of claim 12, wherein applying the optical coating includes applying an optical reflection coating configured to reflect light of a predetermined wavelength from the plurality of microLEDs.

18. The method of claim 12, further comprising depositing an encapsulation layer over the plurality of bank structures.
